(19) United States
(12) Patent Application Publication
(10) Pub. No.: US 2015/0107670 A1
(43) Pub. Date: Apr. 23, 2015

(54) CONCENTRATING SOLAR CELL MODULE PANEL HAVING STIFFNESS AND CONCENTRATING PHOTOVOLTAIC GENERATION SYSTEM COMPRISING SAME

(71) Applicant: ANYCASTING CO., LTD., Seoul (KR)

(72) Inventors: Sungbin Kim, Goyang-si (KR); Jangkyun Kim, Bucheon-si (KR); Byungwook Kim, Incheon-si (KR); Chankyu Park, Seoul (KR)

(21) Appl. No.: 14/404,450

(22) PCT Filed: Sep. 27, 2012
(86) PCT No.: PCT/KR2012/007842

§ 371 Date: Nov. 26, 2014

(30) Foreign Application Priority Data
May 30, 2012 (KR) 10-2012-0057357
Sep. 27, 2012 (KR) 10-2012-0107893

(51) Int. Cl. H01L 31/054; H02S 30/10

(52) U.S. Cl. CPC H01L 31/0543; H02S 30/10
USPC 136/259

(57) ABSTRACT

Disclosed is a concentrating solar cell module panel includes: a frame including a side plate and a base plate; carriers that are provided on the base plate at position spaced apart from each other at regular intervals, and each of which is provided with a solar cell; and a lens plate that is provided on an upper end of the frame and concentrates incident light on each of the solar cells. The side plate includes a transverse plate and a longitudinal plate longer than the transverse plate. The base plate comprises a plurality of base plate pieces arranged in a longitudinal direction of the concentrating solar cell module panel and coupled to each other, each of the base plate pieces being coupled to a lower portion of the longitudinal plate by a screw.

### CROSS REFERENCE TO PRIOR APPLICATIONS

This application is a National Stage Application of PCT International Patent Application No. PCT/KR2012/007842 filed on Sep. 27, 2012, under 35 U.S.C. §371, which claims priority to Korean Patent Application Nos. 10-2012-0057357 filed on May 30, 2012, and 10-2012-0107893 filed on Sep. 27, 2012 which are all hereby incorporated by reference in their entirety.

### TECHNICAL FIELD

The present invention generally relates to concentrating solar cell module panels and concentrating photovoltaic generation systems having the same. More particularly, the present invention relates to a concentrating solar cell module panel that has a comparatively high stiffness and is configured such that manufacture and assembly thereof can be facilitated, and a concentrating photovoltaic generation system that has the concentrating solar cell module panel and thus can be configured such that need of a frame structure required to maintain the stiffness of the panel is minimized so that the overall construction of the system can be simplified. This application claims the benefit of Korean Patent Application No. 10-2012-0057357, filed on May 30, 2012, and Korean Patent Application No. 10-2012-0107893, filed on Sep. 27, 2012, which are hereby incorporated by reference in its entirety into this application.

### BACKGROUND ART

Hitherto, use of photovoltaic (PV) apparatuses using solar light has greatly increased. Particularly, photovoltaic apparatuses using silicon solar cells are mainly used.

As technology pertaining to high efficiency III-V compound semiconductor multi-junction solar cells has rapidly progressed in recent years, studies on concentrating photovoltaic (CPV) apparatuses using inexpensive devices concentrating solar light on multi-junction solar cells are being actively conducted.

Multi-junction solar cells have high energy conversion efficiency compared to that of silicon solar cells. Generally, multi-junction solar cells have an energy efficiency of more the 35% while silicon solar cells have an energy efficiency of approximately 20%. Specially, under conditions of light concentration, some multi-junction solar cells have energy efficiency of more the 40%.

A concentrating solar cell module using such multi-junction solar cells includes solar cells, a primary lens primarily concentrating solar light, and a secondary lens secondarily concentrating on the solar cells the solar light that has been concentrated by the primary lens. The solar cells are mounted to a cell mount such as a circuit board, or a receiver, for example, introduced in Korean Patent Unexamined Publication No. 10-2010-0135200.

Concentrating photovoltaic generation systems are configured in such a way that a plurality of concentrating solar cell modules are provided in an array form on a support frame. Furthermore, the concentrating photovoltaic generation systems include a tracking device rotating the solar cell module array such that the solar cell modules can be maintained to be perpendicular to the sun, thus enhancing the efficiency of the multi-junction solar cells.

A representative example of such a concentrating photovoltaic generation system was proposed in Korean Patent Registration No. 10-1003539 (hereinafter, referred to as a ‘conventional art’), entitled “Ground solar cell array.”

The conventional art relates to a solar cell array using III-V compound semiconductor solar cells. As shown in FIGS. 1 and 2, a concentrating photovoltaic generation system according to the conventional art includes a center support 1, a support frame 2, a plurality of solar cell sub-arrays or panels 3, and an actuator rotating the center support 1 and the support frame 2 such that the solar cell array can be maintained to be perpendicular to the rays of the sun. The sub-arrays or panels 3 are formed by stacking modules 4 on top of another.

However, as shown in FIG. 2, because the sub-arrays or panels 3 are formed by stacking the modules 4 on top of each another, a drooping phenomenon of modules 5 disposed outside of the support frame 2 occurs due to their own weight. In this case, there is a problem in that some of the modules 5 are not perpendicular to the rays of the sun although the actuator rotates the support frame 2.

To overcome the above problem, a separate frame structure for preventing the modules 4 disposed outside of the support frame 2 from drooping must be provided on the sub-arrays or panels 3 including the modules 4 although the frame structure is not proposed in the conventional art. Furthermore, as shown in FIG. 1, the support frame 2 supporting the horizontally-arranged panels 3 has a structure that is inevitably complex due to a requirement to maintain the stiffness of the panels 3. Consequently, the overall construction of the concentrating photovoltaic generation system is complex. The weight of the system also increases, thus causing the load applied to the actuator to be increased. Hence, an actuator having a comparatively large capacity is required, thereby increasing the production cost of the system.

### DISCLOSURE

### Technical Problem

Accordingly, the present invention has been made keeping in mind the above problems occurring in the prior art, and an object of the present invention is to provide a concentrating solar cell module panel that has a comparatively high stiffness and is configured such that manufacture and assembly thereof can be facilitated.

Another object of the present invention is to provide a concentrating photovoltaic generation system that is provided with a concentrating solar cell module panel having a comparatively high stiffness and thus can be configured such that a need of a frame structure for supporting the panel is minimized so that the overall construction of the system can be simplified.

### Technical Solution

In order to accomplish the above objects, in an aspect, the present invention provides a concentrating solar cell module panel having a predetermined stiffness, including: a frame including a side plate and a base plate; carriers provided on the base plate at position spaced apart from each other at a predetermined interval, each of the carriers being provided with a solar cell; and a lens plate provided on an upper end of the frame, the lens plate concentrating incident light on each of the solar cells. The side plate includes a transverse plate and a longitudinal plate longer than the transverse plate. The base plate comprises a plurality of base plate pieces arranged in a longitudinal direction of the concentrating solar cell module panel and coupled to each other, each of the base plate pieces being coupled to a lower portion of the longitudinal plate by a screw.

In another aspect, the present invention provides a concentrating photovoltaic generation system including a concentrating solar cell module panel having a predetermined stiffness. The concentrating photovoltaic generation system includes: a support member; a support frame rotatably supported on the support member; a plurality of solar cell module panels each extending a predetermined length in a longitudinal direction and having a predetermined stiffness, the solar cell module panels being arranged in one direction and supported by the support member; a bracket fastening the solar cell module panels to the support frame; and a tracking device rotating the support frame so that the solar cell module panels can be maintained to be perpendicular to rays of the sun. Each of the solar cell module panels includes: a frame including a side plate and a base plate; carriers provided on the base plate at position spaced apart from each other at a predetermined interval, each of the carriers being provided with a solar cell; and a lens plate provided on an upper end of the frame, the lens plate concentrating incident light on each of the solar cells. The side plate includes a transverse plate and a longitudinal plate longer than the transverse plate. The base plate comprises a plurality of base plate pieces arranged in a longitudinal direction of the concentrating solar cell module panel and coupled to each other, each of the base plate pieces being coupled to a lower portion of the longitudinal plate by a screw.

### Advantageous Effects

In a concentrating solar cell module panel according to the present invention having the above-mentioned construction, a plurality of concentrating solar cell modules are integrally provided on a single frame that is comparatively long in a longitudinal (or transverse) direction and has a comparatively high stiffness. Therefore, the panel can be reliably prevented from drooping despite a simple construction.

Furthermore, in the concentrating solar cell module panel according to the present invention, each of a base plate and side plates of the frame having a comparatively high stiffness is integrally manufactured by extruding molding. The side plates and the base plate that are integrally manufactured by extrusion molding can be easily assembled with each other.

Meanwhile, a concentrating photovoltaic generation system according to the present invention includes a concentrating solar cell module panel having a comparatively high stiffness so that a need of a support frame structure for supporting the panel can be minimized, whereby the overall construction of the system can be simplified.

In the concentrating photovoltaic generation system according to the present invention, the concentrating solar cell module panel having a comparatively high stiffness can be easily fastened to the support frame by a bracket. Therefore, the overall assembly process of the system can be facilitated.

### DESCRIPTION OF DRAWINGS

FIGS. 1 and 2 are views showing a concentrating photovoltaic generation system according to a conventional technique;

FIG. 3 is a perspective view illustrating a concentrating solar cell module panel according to an embodiment of the present invention;

FIG. 4 is a transverse cross-sectional view of the concentrating solar cell module panel of FIG. 3;

FIG. 5 is an exploded perspective view illustrating the coupling of a base plate and a longitudinal plate of the concentrating solar cell module panel of FIG. 3;

FIG. 6 is a sectional view showing a portion of the base plate of the concentrating solar cell module panel of FIG. 3;

FIG. 7 is a perspective view illustrating a base plate piece of the base plate;

FIG. 8 is a perspective view illustrating a carrier frame;

FIG. 9 is a sectional view showing a portion of the base plate of the concentrating solar cell module panel provided with secondary optical elements;

FIG. 10 is a partial transverse cross-sectional view illustrating a concentrating solar cell module panel according to another embodiment of the present invention;

FIG. 11 is a partial longitudinal cross-sectional view illustrating the concentrating solar cell module panel of FIG. 10;

FIG. 12 is a view schematically showing carriers arranged on the base plate of the concentrating solar cell module panel of FIG. 10;

FIG. 13 is an enlarged view of portion ‘A’ of FIG. 11;

FIG. 14 is a view schematically illustrating a concentrating photovoltaic generation system according to an embodiment of the present invention;

FIG. 15 is a sectional view schematically showing the concentrating solar cell module panel of FIG. 14 fastened to a support frame by a bracket;

FIG. 16 is a perspective view illustrating the concentrating solar cell module panel of FIG. 14; and

FIG. 17 is a sectional view schematically showing a concentrating solar cell module panel fastened to a support frame by a bracket according to another embodiment of the present invention.

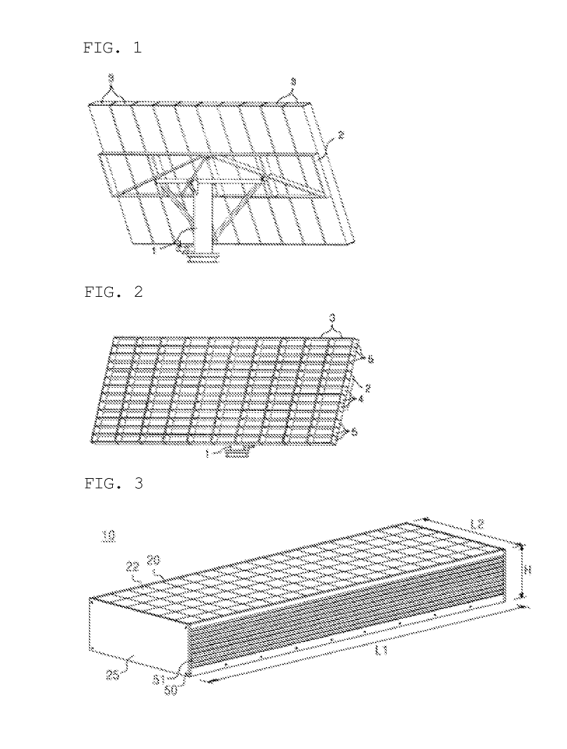

### BEST MODE

Hereinafter, preferred embodiments of the present invention will be described in detail with reference to the attached drawings.

This invention may, however, be embodied in many different forms, and should not be construed as limited to the embodiments set forth herein. Rather, all changes that fall within the bounds of the present invention, or the equivalence of the bounds, are therefore intended to be embraced by the present invention.

In the drawings, the size of each element, the thickness of lines illustrating the element, etc. may be exaggeratedly expressed in the drawings for clarity of illustration, but due to this, the protective scope of the present invention should not be interpreted narrowly.

In this specification, the terms ‘longitudinal direction’ and ‘transverse direction’ are just relative terms for use in explaining the relationship between elements based on the orientation indicated in the drawings. The scope of the present invention is not restricted by these terms.

The present invention relates to a concentrating solar cell module panel that has a comparatively high stiffness and is configured such that manufacture and assembly thereof can be facilitated. The concentrating solar cell module panel according to the present invention is defined as: a panel in which a plurality of concentrating solar cell modules are integrally provided on a frame that is comparatively long; a very large concentrating solar cell module that is comparatively long; a panel having a high stiffness that can be operated by a tracking device such that the panel is oriented perpendicular to the rays of the sun; or a panel in which a plurality of solar cells are arranged in longitudinal and transverse directions in a single space defined in a single comparatively long frame. Hereinafter, a variety of embodiments of such a panel will be described in detail with reference to the attached drawings.

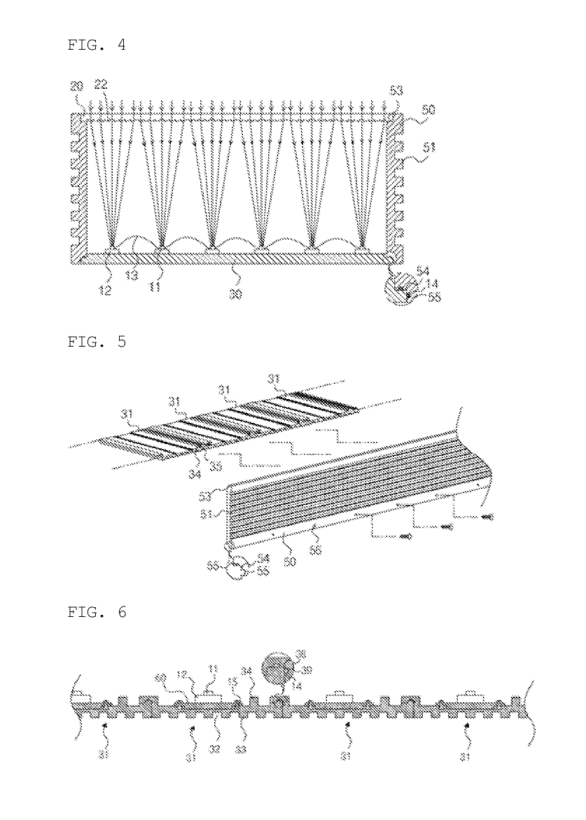

FIG. 3 is a perspective view illustrating a concentrating solar cell module panel according to a first embodiment of the present invention. FIG. 4 is a transverse cross-sectional view of the concentrating solar cell module panel of FIG. 3. FIG. 5 is an exploded perspective view illustrating the coupling of a base plate and a longitudinal plate.

Referring to FIGS. 3 through 5, the concentrating solar cell module panel 10 according to the first embodiment of the present invention includes a frame, carriers 12 each provided with a solar cell 11, and a lens plate 20.

The frame extends a predetermined length in a longitudinal direction and has comparatively high stiffness. The frame includes a base plate 30 and side plates and is configured to be open on an upper side thereof. The side plates include transverse plates 25 each extending a predetermined length in the transverse direction, and longitudinal plates 50 each of which is longer than the transverse plate 25.

Each solar cell 11 is an element converting solar energy into electric energy. Preferably, a high efficiency Ill-V compound semiconductor multi-junction solar cell is used as the solar cell 11. Each carrier 12 is configured such that the solar cell 11, along with other elements, is mounted to a circuit board. A receiver typically used in this art pertaining to the present invention may be used as the carrier 12. That is, in the present invention, the carrier 12 formed in such a way that the solar cell 11 is provided on the circuit board can be configured in a variety of forms. The term ‘carrier’ is used as a term including a receiver. The carriers 12 are provided at positions spaced apart from each other at predetermined intervals. Each carrier 12 is provided with a connector. The carriers 12 are connected in parallel or series to each other by electrically connecting the connectors of the carriers 12 using wires 13.

The lens plate 20 is provided on an upper end of the frame to concentrate incident solar light on the solar cells 11. The lens plate 20 includes a plurality of patterned parts 22 concentrating incident solar light on the respective solar cells 11. Each patterned part 22 preferably has the same structure as that of a Fresnel lens. That is, the lens plate 20 is configured in such a way that a plurality of Fresnel lens patterned parts is formed in a plate.

Furthermore, the lens plate 20 may be made of a single plate having a plurality of Fresnel lens patterned parts. More preferably, the lens plate 20 is made of a plurality of lens plate pieces that respectively include patterned parts 22 and are arranged on the upper end of the frame.

In the concentrating solar cell module panel 10 according to the present invention, a plurality of concentrating solar cell modules is integrally provided on the single frame having a comparatively high stiffness. In this way, a need of a frame structure required to maintain the stiffness can be minimized despite reliably preventing the solar cell module panel 10 from drooping. The frame according to the present invention itself has a comparatively high stiffness despite being comparatively long in the longitudinal direction. Hereinafter, the construction of the frame will be explained.

The frame includes the base plate 30 and the side plates. The side plates include the transverse plates 25 each extending a predetermined length in the transverse direction, and the longitudinal plates 50 each of which is longer than the transverse plate 25.

Furthermore, a plurality of ribs for enhancing the stiffness is provided on each longitudinal plate 50 extending a predetermined length so that the frame itself can have a sufficient stiffness despite having a comparatively long length.

As shown in the drawings, the ribs may include heat dissipation ribs 51 that protrude from an outer surface of each longitudinal plate 50 and are arranged apart from each other at regular intervals. As such, if the heat dissipation ribs 51 are provided on the outer surface of the longitudinal plate 50, the frame can not only have an increased stiffness but heat transferred from the closed interior of the frame to the longitudinal plate 50 can also be more effectively dissipated to the outside because the contact area between the longitudinal plate 50 and the outside is increased by the heat dissipation ribs 51.

Generally, the temperature of the closed interior of the concentrating solar cell module 10 increases to a very high degree because of a greenhouse effect. A high efficiency Ill-V compound semiconductor multi-junction solar cell that is typically used as each solar cell 11 of the concentrating solar cell module is disadvantageous in that the efficiency is rapidly reduced as the temperature increases. Given this, the concentrating solar cell module panel 10 according to the present invention is configured such that the heat dissipation ribs 51 are provided on the outer surface of the longitudinal plates 50. Thereby, the stiffness of the solar cell module panel 10 can be enhanced and, in addition, heat can be effectively dissipated from the closed interior of the frame to the outside so that the efficiency of the solar cells 11 can be enhanced.

Furthermore, a plurality of ribs may be provided on an outer surface of each transverse plate 25 in the same manner as the longitudinal plate 50. Although the two transverse plates 25 are respectively provided on the opposite ends of the frame in this embodiment, the present invention is not limited to this embodiment. For example, an additional transverse plate 25 may be provided in a medial portion of the frame so as to further enhance the stiffness of the frame.

A stepped part 53 is formed on an upper end of an inner surface of each longitudinal plate 50 so that the lens plate 20 is supported on the stepped parts 53 of the longitudinal plates 50. A coupling part 54 is formed in a lower end of the inner surface of each longitudinal plate 50 so that the base plate 30 is coupled to the coupling parts 54 of the longitudinal plates 50. Not only the stepped part 53 but also the coupling part 54 has a stepped shape.

A plurality of coupling holes 56 are formed in a lower portion of each longitudinal plate 50 so that the base plate 30 is coupled to the longitudinal plate 50 by screws. Filled with a sealant such as silicon, a sealing groove 55 is formed in the coupling part 54. The longitudinal plate 50 is coupled to the base plate 30 by screws after the sealing groove 55 is filled with sealant. By virtue of the sealant, the interior of the frame can be further reliably sealed.

Preferably, the heat dissipation ribs 51, the stepped part 53, the coupling part 54 and the sealing groove 55 have constant cross-sections and extend in the longitudinal direction of the longitudinal plate 50 such that the longitudinal plate 50 can be manufactured by extrusion molding. As such, because the longitudinal plate 50 having the above-mentioned cross-section is integrally manufactured by extrusion molding before being assembled with the frame, the manufacture and assembly processes can be facilitated.

The frame extends a predetermined length. Preferably, the length of the frame is about 3 to about 10 times the width thereof. The height of the frame is about 1/20 to about 1/10 of the length thereof. That is, the length L1 of the longitudinal plate 50 is about 5 to about 10 times the length L2 of the transverse plate 25. The height H of the longitudinal plate 50 is about 1/20 to about 1/10 of the length L1 thereof.

The height of the frame, that is, the height H of the longitudinal plate 50, is the distance between the lens plate 20 and the solar cells 11. Here, the distance between the lens plate 20 and the solar cells 11 may change depending on the size of each patterned part provided on the lens plate 20 or the size of the solar cell 11. Therefore, it is preferable that the height of the frame can be appropriately changed depending on the size of the longitudinal plate 50 that can be manufactured by extrusion molding.

At present, the height of the longitudinal plate 50 that can be integrally manufactured by extrusion molding ranges from about 25 cm to about 50 cm, and the length thereof ranges from about 4 m to about 6 m. With regard to the optimized size of the frame in consideration of manufacture and maintenance in stiffness of the frame, it is preferable that the longitudinal plate 50 has a size that can be integrally manufactured by extrusion molding, in other words, the length of the longitudinal plate 50 ranges from about 4 to about 6 m and the height thereof ranges from about 25 cm to about 50 cm. Furthermore, it is preferable that the length of the transverse plate 25 ranges about 1 m to about 1.2 m. If the frame has the above-mentioned size, the carriers 12 can be arranged such that six carriers 12 are arranged in the transverse direction to form a transverse carrier array, and twenty transverse carrier arrays are arranged in the longitudinal direction. In this case, a total of about 120 solar cells 11 or more can be provided. The present invention is not limited to this. Of course, the sizes of the frame and the longitudinal plate 50 can be changed depending on the purpose of design or the development of the extrusion molding technology.

The base plate 30, the longitudinal plates 50 and the transverse plates 25 that form the frame are preferably made of aluminum that is light, has comparatively high stiffness, and has high heat conductivity. However, the present invention is not limited to this.

The base plate 30 includes a plurality of base plate pieces 31 each of which has a predetermined width with respect to the longitudinal direction and that are arranged in the longitudinal direction and are coupled to each other. Each base plate piece 31 is coupled to a lower surface of the longitudinal plate 50 by screws and has a length corresponding to that of the transverse plate 25.

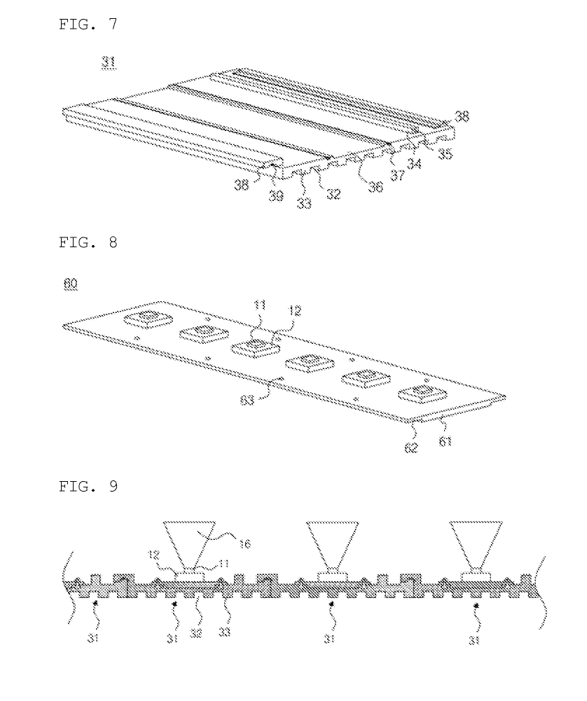

FIG. 6 is a sectional view showing a portion of the base plate of the concentrating solar cell module panel of FIG. 3. FIG. 7 is a perspective view illustrating a base plate piece of the base plate. FIG. 8 is a perspective view illustrating a carrier frame.

Referring to FIGS. 6 through 8, heat dissipation ribs 33 protrude from the lower surface of each base plate piece 31. A coupling rib 34 protrudes from the upper surface of the base plate piece 31. The coupling rib 34 has a coupling hole 35 through which the longitudinal plate 50 is coupled to the base plate piece 31 by a screw.

The stiffness of the base plate piece 31 can be enhanced by the heat dissipation ribs 33 and the coupling rib 34. The heat dissipation ribs 33 increase the contact area between the base plate piece 31 and the outside so that heat transferred from the closed interior of the frame to the base plate piece can be effectively transferred and dissipated to the outside. Furthermore, because the coupling hole 35 for use in screw-coupling the base plate piece 31 to the longitudinal plate 50 is formed in the coupling rib 34, the operation of forming the coupling hole 35 in the base plate piece 31 that is made of thin board can be facilitated.

The concentrating solar cell module panel 10 according to the embodiment of the present invention further includes a carrier frame 60 that extends a predetermined length in the transverse direction to fix in place at least two of the carriers 12 arranged in the transverse direction.

Two or more carrier frames 60 each of which fixes in place some of the carriers 12 arranged in the transverse direction may be provided. Alternatively, as shown in FIG. 8, all of the carriers 12 arranged in the transverse direction may be fixed to the single carrier frame 60.

A seating depression 36 into which the carrier frame 60 is seated is formed in an upper surface of the base plate piece 31. T-grooves 37 are formed on opposite sides of the seating depression 36. Fastening members 15 for use in fastening the carrier frame 60 seated in the seating depression 36 to the base plate piece 31 are inserted into the respective T-grooves 37 and prevented from being removed upwards from the T-grooves 37. The carrier frame 60 includes a seating part 61 that is seated into the seating depression 36, and wing parts 62 that extend outwards from the seating part 61 and cover the T-grooves 37. Fastening-member passing holes 63 are formed in the wing parts 62 so that the fastening members 15 disposed in the T-grooves 37 are inserted into the corresponding fastening-member holes 63. For example, if each fastening member 15 is a bolt or T-bolt, the carrier frame 60 is fastened to the base plate piece 31 by inserting the bolt or T-bolt into the corresponding fastening-member hole 63 and tightening a separate nut over the bolt or T-bolt. If the fastening member 15 is a nut or T-nut, the carrier frame 60 is fastened to the base plate piece 31 by inserting a separate bolt into the fastening-member hole 63 and tightening the bolt into the nut or T-nut.

As such, if the carrier frame 60 extending a predetermined length in the transverse direction is used, and the carriers 12 arranged in the transverse direction are fastened to the carrier frame 60 while the construction for fastening the carrier frame 60 to the base plate piece 31 is provided, the carrier frame 60 has only to be fastened to the base plate piece 31 without separately or individually fastening the carriers 12 to the base plate piece 31. Therefore, the general assembly process can be facilitated.

Connection parts 38 are provided on opposite edges of the base plate piece 31 so that each base plate piece 31 can be coupled to other adjacent base plate pieces 31 by the connection parts 38. A sealing groove 39 filled with sealant is formed in the connection part 38. As such, if the base plate pieces 31 are coupled to each other with sealant charged in the sealing grooves 39, the interior of the frame can be further reliably sealed.

Furthermore, preferably, the heat dissipation ribs 33, the coupling rib 34, the seating depression 36, the T-grooves 37, the connection parts 38 and the sealing groove 39 have constant cross-sections and extend in the transverse direction such that the base plate piece 31 can be manufactured by extrusion molding. In this case, the base plate pieces 31 each having the above-mentioned constant cross-section are manufactured in such a way that a plate for forming the base plate pieces 31 is integrally formed by extrusion molding and then cut by a desired length to form the base plate pieces 31. The manufacture base plate pieces 31 are thereafter assembled with each other to form the frame. In this way, the processes of manufacturing and assembling the base plate pieces 31 can be facilitated.

In the concentrating solar cell module panel 10 according to the present invention, so as to facilitate the coupling of the base plate 30 to the longitudinal plates 50, the base plate 30 must have the above-mentioned cross-section in the transverse direction, and the longitudinal plate 50 must have the above-mentioned cross-section in the longitudinal direction. In addition, the base plate 30 must have a constant transverse cross-section, and the longitudinal plate 50 must have a constant longitudinal cross-section. This is preferable in terms of manufacture because the base plate 30 or the longitudinal plate 50 can be integrally manufactured through a single extrusion molding process. However, the size of the plate that can be integrally manufactured through a single extrusion molding process is limited. Given this, the concentrating solar cell module panel 10 according to the present invention is configured such that: the longitudinal plate 50 is integrally manufactured through an extrusion molding process so as to enhance the stiffness of the panel 10; and the base plate 30 is formed by longitudinally arranging the base plate pieces 31 each having an appropriate width to be manufactured by extrusion molding and then coupling the base plate pieces 31 to each other. Thereby, the manufacture of each plate and the overall assembly process can be facilitated. Furthermore, in this case, the base plate pieces 31 of the base plate 30 can be easily manufactured in such a way that after a plate is integrally formed by extrusion molding to have a predetermined length, the plate is cut by a desired length.

As shown in FIG. 9, the concentrating solar cell module panel 10 according to the present invention may further include a secondary optical element 16 that is provided between the lens plate 20 and each solar cell 11 and secondarily concentrates, on the solar cell 11, light concentrated by the corresponding pattern part 22 of the lens plate 20. The secondary optical element 16 may have a lens structure or a reflector structure. The present invention is not limited to an embodiment of the detailed structure of the secondary optical element 16.

Hereinafter, a concentrating solar cell module panel according to another embodiment of the present invention will be explained with reference to the attached drawings. For the sake of explanation, the same reference numerals are used to designate the same or similar components as those of the panel according to the above-described embodiment, and further explanation thereof is substituted by the detailed description of the above-described embodiment.

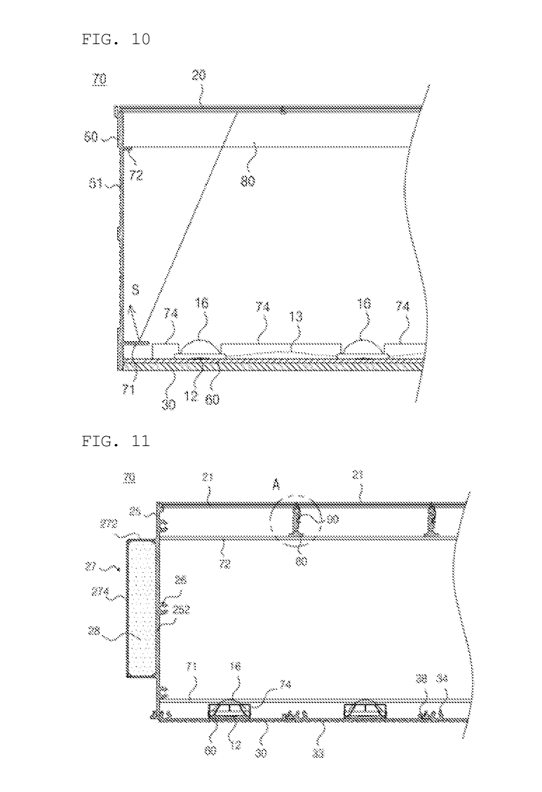

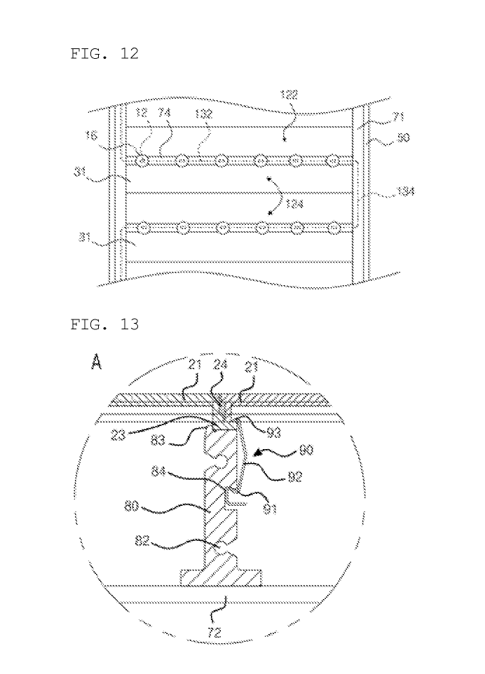

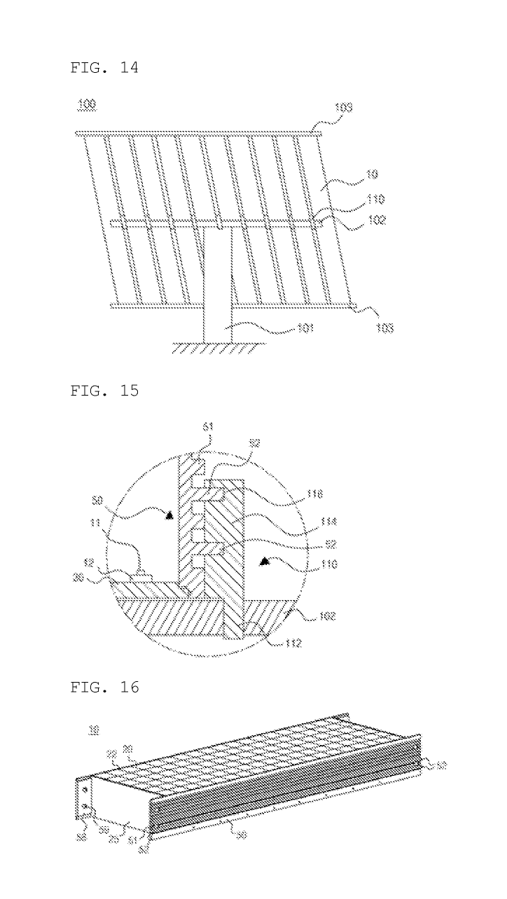

FIG. 10 is a partial transverse cross-sectional view illustrating a concentrating solar cell module panel according to another embodiment of the present invention. FIG. 11 is a partial longitudinal cross-sectional view illustrating the concentrating solar cell module panel of FIG. 10. FIG. 12 is a view schematically showing carriers arranged on the base plate of the concentrating solar cell module panel of FIG. 10. FIG. 13 is an enlarged view of portion ‘A’ of FIG. 11.

Referring to FIGS. 10 through 13, the concentrating solar cell module panel 70 according to this embodiment of the present invention includes: a frame having side plates and a base plate 30; carriers 12 that are provided on the base plate at positions spaced apart from each other at regular intervals and each of which is provided with a solar cell 11; and a lens plate 20 provided on an upper end of the frame to concentrate incident solar light on the solar cells 11.

The side plates include transverse plates 25 and longitudinal plates 50. The lens plate 20 includes a plurality of lens plate pieces 21 arranged on the upper end of the frame. The base plate 30 includes a plurality of base plate pieces 31 each of which has a predetermined width with respect to the longitudinal direction and that are arranged in the longitudinal direction and are coupled to each other.

The concentrating solar cell module panel 70 according to this embodiment further includes: a carrier frame 60 to which carriers 12 arranged in the transverse direction are fastened; a wire 13 connecting the carriers 12 in parallel or series to each other; and a secondary lens (secondary optical element, SOE) 16 that is provided between the lens plate 20 and each solar cell 11 and secondarily concentrates, on the solar cell 11, light concentrated by the lens plate 20.

Furthermore, the concentrating solar cell module panel 70 according to this embodiment further includes: a wire cover 74 covering the wire 13; supports 80 supporting the lens plate pieces 21; and elastic members 90 fastening the lens plate pieces 21, supported on the supports 80, to the supports 80.

Each longitudinal plate 50 includes a plurality of ribs provided to enhance the stiffness of the longitudinal plate 50. The ribs may include heat dissipation ribs 51 that protrude from an outer surface of each longitudinal plate 50 to a predetermined height and are arranged at positions spaced apart from each other at regular intervals. The heat dissipation ribs 51 can enhance the stiffness of the longitudinal plate 50 and increase the contact area between the longitudinal plate 50 and the outside to improve the heat dissipation effect. Furthermore, each longitudinal plate 50 further includes a reflective rib 71 protruding from a lower portion of an inner surface of the longitudinal plate 50. The reflective rib 71 enhances the stiffness of the longitudinal plate 50 and reflects solar light S offset from the lens plate 20.

The reflective rib 71 is provided to avoid the problems caused by offset solar light S accidently entering the panel 70 rather than being concentrated from the lens plate 20 on the solar cells 11. Such offset solar light S may enter elements provided around the carriers 12 of the base plate 30 and damage the elements. Given this, the reflective rib 71 protrudes inward from the lower portion of the inner surface of the longitudinal plate 50 and reflects offset solar light S to prevent the offset solar light S from entering the elements around the carriers 12.

The offset solar light S is caused when solar light does not perpendicularly enter the lens plate 20. The wires 13 electrically connecting the carriers 12 to each other are mainly damaged by the offset solar light S. Particularly, in the structure of the concentrating solar cell module panel 10 or 70 according to the present invention in which a plurality of carriers 12 are arranged in the transverse direction to form an array and such arrays are arranged in the longitudinal direction to form another array, a large number of wires 13 are required to connect the carriers 12 in parallel or series to each other. Therefore, it is necessary to prevent these wires 13 from being damaged by the offset solar light S. For this, the solar cell module panel 70 according to this embodiment includes the reflective rib 71 protruding inward from the lower portion of the inner surface of the longitudinal plate 50, thus avoiding the above-mentioned problem.

Referring to FIG. 12, the carriers 12 are arranged in such a way that a plurality of carriers 12 are transversely arranged on a transverse array 122, and a plurality of transverse arrays 122 are longitudinally arranged to form a longitudinal array 124. The carriers 12 arranged in the above-mentioned manner are connected to each other by the wires 13.

For example, the carriers 12 forming each transverse array 122 are connected to each other by transverse connection wires 132. With regard to the longitudinal array 124, the transverse arrays 122 are connected to each other in such a way that the carrier 12 disposed on an end of each transverse array 122 is connected to the carrier 12 disposed on a corresponding end of the adjacent transverse array 122 by a longitudinal connection wire 134. Here, the transverse connection wires 132 can be protected by the wire cover 74. However, the longitudinal connection wire 134 is disposed at one side of the perimeter of the panel 70. Therefore, it is difficult to cover the longitudinal connection wire 134 with the wire cover 74 because of the assembly structure of the panel 70. Thus, a separate means for protecting the longitudinal connection wire 134 is required. In the panel 70 according to this embodiment, the reflective rib 71 that protrudes inward from the lower portion of the inner surface of the longitudinal plate 50 functions not only to enhance the stiffness of the longitudinal plate 50 but also to protect the longitudinal connection wires 134.

Preferably, the reflective rib 71 extends in the longitudinal direction and has a constant cross-section such that the reflective rib 71 can be integrally formed with the longitudinal plate 50 through an extrusion molding process in the same manner as that of the heat dissipation rib 51.

Each carrier frame 60 is provided to facilitate the coupling the carriers 12 arranged in the transverse direction to the base plate 30. Although the carrier frame 60 can have a variety of shapes, it is preferable that the carrier frame 60 have a heat pipe frame structure provided with a heat pipe (not shown) that can dissipate heat generated from the carriers 12.

Meanwhile, the lens plate 20 is made of a plurality of lens plate pieces 21 that respectively have patterned parts 22 and are arranged on the upper end of the frame. In this embodiment, the lens plate pieces 21 are fastened to the frame by the supports 80 and the elastic members 90.

Each support 80 has a length approximately corresponding to the length of the transverse plate 25. The supports 80 are arranged in the longitudinal direction at regular intervals and supported by support ribs 72 protruding from an upper portion of the inner surface of the respective longitudinal plates 50.

That is, the ribs provided on each longitudinal plate 50 to enhance the stiffness of the longitudinal plate 50 may further include the support ribs 72 provided on the upper portion of the inner surface of the longitudinal plate 50 not only to enhance the stiffness of the longitudinal plate 50 but also to support the supports 80.

Preferably, the support ribs 72 extend in the longitudinal direction and have a constant cross-section such that the support ribs 72 can be integrally formed with the longitudinal plate 50 through an extrusion molding process in the same manner as that of the heat dissipation rib 51 or the reflective rib 71.

The structure of fastening the lens plate pieces 21 to the upper end of the frame using the support 80 and the elastic member 90 will be described in detail with reference to FIG. 13.

The supports 80 extend in the transverse direction and are supported on the support ribs 72 that are provided on the upper portion of the longitudinal plates 50 facing each other. Each support 80 has: a coupling hole 82 through which the support 80 is fastened to the longitudinal plate 50 by a screw; and a stop protrusion 83 provided on an upper end of the support 80 so that a stopper 23 provided on an end of the lens plate piece 21 is stopped on the support 80 by the stop protrusion 83. The support 80 further includes a coupling depression 84 to which the elastic member 90 for fixing the lens plate piece 21 in place is locked. Preferably, the support 80 has a constant transverse cross-section so that it can be integrally formed by extrusion molding.

The elastic member 90 includes: a bent part 91 that is provided on a lower end of the elastic member 90 and is locked to the corresponding coupling depression 84; an elastic member body 92 that extends upward from the bent part 91 to have a shape capable of providing elastic force; and a locking end 93 that is bent from an upper end of the elastic member body 92 and fixes in place the lens plate piece 21 supported on the support 80.

The support 80 placed on the support rib 72 is coupled to the longitudinal plate 50 by a screw. The lens plate piece 21 is fastened to the support 80 by the elastic member 90 while the stopper 23 of the lens plate piece 21 is stopped and supported by the stop protrusion 83 of the support 80.

Furthermore, after one of the lens plate pieces 21 is fastened to the upper end of the frame in the above-mentioned manner, one side edge of another adjacent lens plate piece 21 is supported on the support 80 on which the one of the lens plate pieces 21 has been supported, and the stopper 23 provided on the other side edge of the adjacent lens plate piece 21 is stopped and supported on the stop protrusion 83 of another adjacent support 80 spaced apart from the first support 80 by a predetermined distance. Subsequently, the adjacent lens plate piece 21 is fixed in place by another elastic member 90. A space between the lens plate pieces 21 is sealed by a sealing member 24 made of silicon or the like so that the interior of the frame can be reliably sealed.

A coupling rib 26 for screw-coupling with the longitudinal plate 50 is provided on an inner or outer surface of each transverse plate 25. A ventilation unit 27 having therein a space for installation of a filter 28 is provided on the outer surface of the transverse plate 25.

The coupling rib 26 functions not only to enhance the stiffness of the transverse plate 25 but also to facilitate the screw-coupling with the longitudinal plate 50. The ventilation unit 27 functions as a passage for discharging air in the closed frame. The ventilation unit 27 includes two side surface part 272 that extend outward from the outer surface 252 of the transverse plate 25, and a front surface part 274 that connects the two side surface parts 272 to each other so that the space in which the filter 28 is disposed is defined between the outer surface 252 and the front surface part 274.

The ventilation unit 27 may be integrally formed with the transverse plate 25. Preferably, the coupling rib 26 and the ventilation unit 27 extend predetermined lengths in the transverse direction and have constant cross-sections so that the transverse plate 25 can be integrally formed by extrusion molding.

Typical concentrating solar cell modules are provided with a separate ventilation device for discharging air from a closed internal space to the outside. Such a structure of the typical concentrating solar cell modules is disadvantageous in that a separate manufacturing process is required to install the ventilation device.

Unlike the typical concentrating solar cell modules, the panel 70 according to this embodiment is configured such that such when the transverse plate 25 is manufactured, a ventilation device is integrally formed with the transverse plate 25 without requiring a separate installation process. For this, the ventilation unit 27 has a constant cross-section and extends a predetermined length in the transverse direction to make it possible to integrally form the transverse plate 25 through an extrusion molding process.

Furthermore, although it is not shown in the drawings, a ventilation hole (not shown) is formed in the outer surface 252 of the transverse plate 25 so that air in the frame can communicate with the ventilation unit 27. The ventilation hole may be formed in the transverse plate 25 through a separate process after the transverse plate 25 has been manufactured by extrusion molding. Alternatively, the ventilation hole may be formed to have a constant cross-section and a predetermined transverse length so that the ventilation hole is integrally formed with the transverse plate 25 when the transverse plate 25 is manufactured by extrusion molding.

Although it is not shown in the drawings, openings formed in front and rear ends of the ventilation unit 27 based on the drawings are closed by the filter 28 provided in the space defined in the ventilation unit 27. Air in the frame is drawn into the ventilation unit 27 through the ventilation hole before being discharged to the outside via the filter 28.

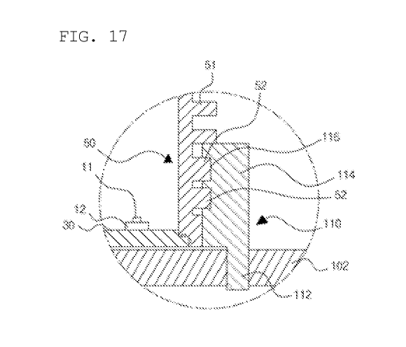

FIG. 14 is a view schematically illustrating a concentrating photovoltaic generation system according to an embodiment of the present invention. FIG. 15 is a sectional view schematically showing the concentrating solar cell module panel of FIG. 14 fastened to a support frame by a bracket. FIG. 16 is a perspective view illustrating the concentrating solar cell module panel of FIG. 14. FIG. 17 is a sectional view schematically showing a concentrating solar cell module panel fastened to a support frame by a bracket according to another embodiment of the present invention.

Referring to FIGS. 14 through 17, the concentrating photovoltaic generation system 100 according to an embodiment of the present invention includes: a support member 101; a support frame 102 rotatably supported on the support member 101; a plurality of solar cell module panels 10 that are arranged in one direction and supported by the support frame 102; a bracket 110 fastening the solar cell module panels 10 to the support frame 102; and a tracking device rotating the support frame 102 so that the solar cell module panels 10 can be maintained to be perpendicular to rays of the sun.

The solar cell module panels 10 or 70 extend a predetermined length in the longitudinal direction and are configured such that they have comparatively high stiffness. Reference numerals and detailed description of the elements of the solar cell module panels 10 or 70 are substituted by the reference numerals and the detailed description of the above-described embodiments.

The bracket 110 fastens each of the solar cell module panels 10 or 70 arranged in one direction to the support frame 102 provided in a direction perpendicular to the direction of the arrangement of the solar cell module panels 10 or 70. The bracket 110 includes: a support-frame coupling part 112 that is provided at a first side and is coupled to the support frame 102; and a panel coupling part 114 that is provided at a second side, for example, in a direction perpendicular to the support-frame coupling part 112, and is coupled to the solar cell module panel 10. The support-frame coupling part 112 and the panel coupling part 114 may be respectively fastened to the support frame 102 and the panel 10 by separate fastening members; however, the present invention is not limited to a detailed construction of the fastening method.

Preferably, the longitudinal plate 50 includes a coupling rib 52 that is coupled to the bracket 110. The panel coupling part 114 has a coupling rib slot 116 into which the coupling rib 52 is fitted. By virtue of the coupling rib 52 and the coupling rib slot 116, the concentrating solar cell module panel 10 can be more reliably supported by the support frame 102.

Furthermore, each panel 10 or 70 according to the present invention includes the ribs to enhance the stiffness of the longitudinal plate 50, wherein the ribs may include coupling ribs 52 that protrude from the outer surface of the longitudinal plate 50 and are coupled to the coupling rib slots 116 of the panel coupling part 114.

As shown in FIGS. 15 and 17, the coupling rib 52 may be configured such that it protrudes from the outer surface of the longitudinal plate 50 to a distance longer than that of the heat dissipation rib 51 provided on the outer surface of the longitudinal plate 50. Alternatively, the coupling rib 52 may be configured such that it is thicker than that of the heat dissipation rib 51. Preferably, as shown in FIG. 17, the coupling rib 52 is comparatively thick and has a short length to which it protrudes outward from the longitudinal plate 50. The reason for this is to make it possible to reliably support a load applied to the coupling rib 52 given the fact that the load is very large because the concentrating solar cell module panel 10 or 70 is heavy.

The concentrating photovoltaic generation system 100 according to this embodiment of the present invention further includes subsidiary frames 103 connecting the opposite ends of the solar cell module panels 10 or 70 arranged in one direction to each other. The longitudinal frame 50 of each solar cell module panel 10 or 70 includes an extension part 58 coupled to the subsidiary frame 103. The extension part 58 has an insert hole 59 into which the corresponding subsidiary frame 103 is inserted.

As such, if the system further includes the subsidiary frames 103 connecting the opposite ends of the solar cell module panels 10 or 70 arranged in one direction to each other, the solar cell module panels 10 or 70 that are comparatively long and are arranged in one direction can be more reliably supported by the subsidiary frames 103. In addition, the opposite ends of the solar cell module panels 10 or 70 can be more reliably prevented from drooping. Moreover, such construction can simplify the structure of the support frame 102 supporting the solar cell module panels 10 and 70.

As described above, the present invention relates to a concentrating solar cell module panel that has sufficient stiffness and can be easily manufactured and assembled, and to a concentrating photovoltaic generation system having the concentrating solar cell module panel. The present invention can be embodied in a variety of forms. Therefore, the present invention is not limited to the embodiments disclosed in this specification. All changes that fall within the bounds of the present invention, or the equivalence of the bounds, should be understood to be embraced by the present invention.

1-18. (canceled)

19. A concentrating solar cell module panel having a predetermined stiffness, comprising:
a frame including a side plate and a base plate;
carriers provided on the base plate at position spaced apart from each other at a predetermined interval, each of the carriers being provided with a solar cell; and
a lens plate provided on an upper end of the frame, the lens plate concentrating incident light on each of the solar cells,
wherein the side plate comprises a transverse plate and a longitudinal plate longer than the transverse plate,
wherein the base plate comprises a plurality of base plate pieces arranged in a longitudinal direction of the concentrating solar cell module panel and coupled to each other, each of the base plate pieces being coupled to a lower portion of the longitudinal plate by a screw.

20. The concentrating solar cell module panel of claim 19, wherein the transverse plate, the longitudinal plate and each of the base plate pieces being integrally manufactured by extrusion molding respectively.

21. The concentrating solar cell module panel of claim 19, wherein a heat dissipation rib protrudes from a lower surface of each of the base plate pieces, a coupling rib protrudes from an upper surface of each of the base plate pieces, and the coupling rib being used in screw-coupling with the longitudinal plate.

22. The concentrating solar cell module panel of claim 21, wherein each of the heat dissipation ribs and the coupling rib has a constant cross-section and extends a predetermined length in a transverse direction of the concentrating solar cell module panel so that each of the base plate pieces can have a constant cross-section and thus be integrally manufactured by extrusion molding.

23. The concentrating solar cell module panel of claim 21, wherein connection parts are provided on respective opposite side edges of each of the base plate pieces, the connection parts being used in coupling with the adjacent base plate pieces, with a sealing groove formed in the connection part,
wherein each of the base plate pieces is coupled to the adjacent base plate pieces after the sealing groove is filled with a sealant,
wherein each of the heat dissipation ribs, the coupling rib, the connection parts and the sealing groove has a constant cross-section and extends a predetermined length in a transverse direction of the concentrating solar cell module panel so that each of the base plate pieces can have a constant cross-section and thus be integrally manufactured by extrusion molding.

24. The concentrating solar cell module panel of claim 19, wherein a coupling rib protrudes from the transverse plate, the coupling rib being used in screw-coupling with the longitudinal plate, and a ventilation unit is provided on an outer surface of the transverse plate, the ventilation unit defining a predetermined space therein.

25. The concentrating solar cell module panel of claim 24, wherein each of the coupling rib and the ventilation unit has a constant cross-section and extends a predetermined length in a transverse direction of the concentrating solar cell module panel so that the transverse plate have a constant cross-section and thus be integrally manufactured by extrusion molding.

26. The concentrating solar cell module panel of claim 19, wherein the longitudinal plate comprises a coupling part coupled to each of the base plate pieces, with a sealing groove formed in the coupling part,
wherein the longitudinal plate is coupled to each of the base plate pieces by a screw after the sealing groove is filled with a sealant.

27. The concentrating solar cell module panel of claim 19, wherein a plurality of ribs protrude from the longitudinal plate so that a stiffness of the longitudinal plate can be enhanced, and each of the ribs has a constant cross-section and extends a predetermined length in a longitudinal direction of the concentrating solar cell module panel so that the longitudinal plate can have a constant cross-section and thus be integrally manufactured by extrusion molding.

28. The concentrating solar cell module panel of claim 27, wherein the ribs comprise heat dissipation ribs protruding from an outer surface of the longitudinal plate at positions spaced apart from each other at a predetermined interval.

29. The concentrating solar cell module panel of claim 28, wherein the ribs further comprise a reflective rib protruding from a lower portion of an inner surface of the longitudinal plate, the reflective rib reflecting solar light offset from the lens plate.

30. The concentrating solar cell module panel of claim 19, further comprising:
a carrier frame to which, of the carriers, at least two carries arranged in a transverse direction of the concentrating solar cell module panel are fastened,
wherein each of the base plate pieces has a seating depression into which the carrier frame is seated.

31. The concentrating solar cell module panel of claim 19, wherein the lens plate comprises a plurality of lens plate pieces arranged on the upper end of the frame and coupled to each other,
the concentrating solar cell module panel further comprising a support supporting the lens plate pieces thereon,
wherein the ribs comprise a support rib protruding from an upper portion of the inner surface of the longitudinal plate, the support rib supporting the support thereon.

32. The concentrating solar cell module panel of claim 31, further comprising
elastic members fastening the respective lens plate pieces supported on the support to the support.

33. A concentrating photovoltaic generation system including a concentrating solar cell module panel having a predetermined stiffness, the concentrating photovoltaic generation system comprising:
a support member;
a support frame rotatably supported on the support member;
a plurality of solar cell module panels each extending a predetermined length in a longitudinal direction and having a predetermined stiffness, the solar cell module panels being arranged in one direction and supported by the support member;
a bracket fastening the solar cell module panels to the support frame; and
a tracking device rotating the support frame so that the solar cell module panels can be maintained to be perpendicular to rays of the sun,
wherein each of the solar cell module panels comprises:
a frame including a side plate and a base plate;
carriers provided on the base plate at position spaced apart from each other at a predetermined interval, each of the carriers being provided with a solar cell; and
a lens plate provided on an upper end of the frame, the lens plate concentrating incident light on each of the solar cells,
wherein the side plate comprises a transverse plate and a longitudinal plate longer than the transverse plate,
wherein the base plate comprises a plurality of base plate pieces arranged in a longitudinal direction of the concentrating solar cell module panel and coupled to each other, each of the base plate pieces being coupled to a lower portion of the longitudinal plate by a screw.

34. The concentrating photovoltaic generation system of claim 33, wherein the transverse plate, the longitudinal plate and each of the base plate pieces being integrally manufactured by extrusion molding respectively.

35. The concentrating photovoltaic generation system of claim 33, wherein a heat dissipation rib protrudes from a lower surface of each of the base plate pieces, a coupling rib protrudes from an upper surface of each of the base plate pieces, and the coupling rib being used in screw-coupling with the longitudinal plate,
wherein each of the heat dissipation ribs and the coupling rib has a constant cross-section and extends a predetermined length in a transverse direction of the concentrating solar cell module panel so that each of the base plate pieces can have a constant cross-section and thus be integrally manufactured by extrusion molding.

36. The concentrating photovoltaic generation system of claim 33, wherein a coupling rib protrudes from the transverse plate, the coupling rib being used in screw-coupling with the longitudinal plate, and a ventilation unit is provided on an outer surface of the transverse plate, the ventilation unit defining a predetermined space therein,
wherein each of the coupling rib and the ventilation unit has a constant cross-section and extends a predetermined length in a transverse direction of the concentrating solar cell module panel so that the transverse plate have a constant cross-section and thus be integrally manufactured by extrusion molding.

37. The concentrating photovoltaic generation system of claim 33, wherein a plurality of ribs protrude from the longitudinal plate so that a stiffness of the longitudinal plate can be enhanced, and each of the ribs has a constant cross-section and extends a predetermined length in a longitudinal direction of the concentrating solar cell module panel so that the longitudinal plate can have a constant cross-section and thus be integrally manufactured by extrusion molding.

38. The concentrating photovoltaic generation system of claim 37, wherein the bracket comprises:
a support-frame coupling part provided at a first side of the bracket; and
a panel coupling part provided at a second side of the bracket, with a coupling rib slot formed in the support-frame coupling part,
wherein the ribs comprise heat dissipation ribs protruding from an outer surface of the longitudinal plate at positions spaced apart from each other at a predetermined interval, and a coupling rib protruding from an outer surface of the longitudinal plate, the coupling rib being fitted into the coupling rib slot.
